(19) United States
(12) Patent Application Publication
(10) Pub. No.: US 2025/0120320 A1
(43) Pub. Date: Apr. 10, 2025

(54) INTERPOSER FOR TRANSDUCER ARRAY

(71) Applicant: GE Precision Healthcare LLC, Waukesha, WI (US)

(72) Inventors: Jean-Luc Diot, Valbonne (FR); Giandonato Stallone, Valbonne (FR); Alexis Hubert, Valbonne (FR); Edouard Da Cruz, Valbonne (FR)

(21) Appl. No.: 18/481,939

(22) Filed: Oct. 5, 2023

(51) Int. Cl. H10N 30/50; G01S 15/89; H10N 30/87; H10N 30/88; H10N 39/00

(52) U.S. Cl. CPC H10N 30/50; G01S 15/8915; H10N 30/874; H10N 30/88; H10N 39/00

(57) ABSTRACT

An architecture of an Electro-Acoustic Module (EAM) of an ultrasound probe is provided. In one example, the EAM includes a rigid interposer positioned between an Application Specific Integrated Circuit (ASIC) chip of the EAM and a flex interconnect coupled to a connector of the EAM, where the interposer facilitates an electrical interconnection between a plurality of transducer cells of the EAM, the ASIC, and the flex interconnect. The interposer may be electrically coupled to the flex interconnect at either a top side or a bottom side of the interposer, via Anisotropic Conductive Film (ACF) and/or Anisotropic Conductive Paste (ACP) or via wire bonds.

### TECHNICAL FIELD

Embodiments of the subject matter disclosed herein relates to ultrasound imaging, and in particular, ultrasound transducer array architecture and manufacture.

### BACKGROUND

Ultrasound imaging is a medical imaging technique for imaging organs and soft tissues in a human body. Ultrasound imaging uses real time, non-invasive high frequency sound waves to produce a series of two-dimensional (2D) and/or three-dimensional (3D) images. Ultrasound transducer cells convert ultrasonic signals to electrical signals and/or convert electrical signals to ultrasonic signals. The ultrasound transducer cells may include conventional piezoelectric transducers and also microelectromechanical systems (MEMS) devices like cMUT (capacitive Micro-machined Ultrasound Transducers) or pMUT (piezoelectric Micro-machined Ultrasound Transducers). The ultrasound transducer cells may be assembled into an Electro-Acoustic Module (EAM) of a transducer array. The EAM may include an Application Specific Integrated Circuit (ASIC) chip that sends electrical signals from the transducer cells to an ultrasound imaging system via a flexible circuit. Due to a high complexity of interconnections between the transducer cells, the ASIC, and the flexible circuit, a cost of the transducer array may be high.

### BRIEF DESCRIPTION

In one embodiment, an EAM of an ultrasound probe comprises an acoustic stack including a plurality of transducer cells; at least one ASIC chip; and a rigid interposer positioned between the at least one ASIC chip and a flexible circuit coupled to one or more connectors of the EAM, the interposer facilitating an electrical interconnection between a plurality of internal contacts of the at least one ASIC and the flexible circuit. The transducer cells may be conventional piezoelectric materials, or MEMS devices like cMUTs or pMUTs. The flexible circuit (e.g., flexible organic substrates, referred to herein as flex) may be electrically coupled to the ASIC using Anisotropic Conductive Film (ACF) and/or Anisotropic Conductive Paste (ACP), or via solder balls or wire bonds. In this way, a first level of interconnection for the EAM is accomplished via the interposer, with simplified outputs for connecting with the flex. As a result, a complexity of a second level of interconnection between the interposer and the flex may be reduced, allowing the flex to have a smaller number of layers, thereby reducing a cost of the flex and an overall cost of the EAM.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The present invention will be better understood from reading the following description of non-limiting embodiments, with reference to the attached drawings, wherein below:

FIG. 1 shows a block diagram of an exemplary ultrasound system that may be used in ultrasound imaging, in accordance with one or more embodiments of the present disclosure;

FIG. 2 shows an exemplary architecture of an EAM, as prior art;

FIG. 3 shows an exploded portion of the EAM of FIG. 2, as prior art;

FIG. 4 shows a first alternative architecture of the exploded portion of the EAM, in accordance with one or more embodiments of the present disclosure;

FIG. 5 shows a second alternative architecture of the exploded portion of the EAM, in accordance with one or more embodiments of the present disclosure;

FIG. 6 shows an exemplary ASIC, as prior art;

FIG. 7 shows an exemplary tiled configuration of ASICs, as prior art;

FIG. 8 shows a plurality of transducers of an acoustic stack, as prior art;

FIG. 9 shows an exemplary interconnection between an ASIC, a transducer array, and a flexible circuit, as prior art;

FIG. 10 shows an exemplary method for assembling an EAM, in accordance with one or more embodiments of the present disclosure;

FIG. 11 shows a first side of an exemplary interposer, in accordance with one or more embodiments of the present disclosure; and

FIG. 12 shows a second side of the exemplary interposer, in accordance with one or more embodiments of the present disclosure.

### DETAILED DESCRIPTION

An ultrasound array architecture and manufacturing method is provided. An ultrasound probe may include a plurality of Electro-Acoustic Modules (EAMs), each EAM including a plurality of transducer cells and one or more dedicated Application Specific Integrated Circuit (ASIC) chips to pilot electrical signals from the transducer cells.

The transducer cells may be piezoelectric ceramic, piezoelectric single crystal or microelectromechanical systems (MEMS) devices like cMUT (capacitive Micro-machined Ultrasound Transducers) or pMUT (piezoelectric Micro-machined Ultrasound Transducers). The MEMS devices may rely on vibration of a membrane with a first electrode to receive and transmit signals. MEMS devices may use real time, non-invasive high frequency (e.g., in a range of 100 KHz to tens of MHz) sound waves to produce a series of two-dimensional (2D) and/or three-dimensional (3D) images. The sound waves may be transmitted by a transmit transducer cell, and the reflections of the transmitted sound waves may be received by a receive transducer cell. The received sound waves may then be processed to display an image of the target. Some types of MEMS devices may be used as a transmit transducer and/or a receive transducer, such as a capacitive micromachined ultrasound transducer (cMUT). The basic structure of a cMUT includes a thin membrane and a support substrate separated by a vacuum cavity. The membrane vibrates when excited with an electrical AC signal. Conversely, an electrical signal is generated when the membrane vibrates due to impinging sound waves.

To be compatible with various probe configurations and to reduce development costs, the ASICs can be tiled to pilot a given probe. To allow such tiling, power supply inputs and inputs and outputs (I/Os) used to pilot the ASICs and transducer cells may be arranged on one side of the ASIC. In one example, a 2×2 ASIC configuration may pilot an array of 6000 transducer cells. Typically, the interconnection between these tiled ASICs and the transducer cells of a transducer array is performed via a flex circuit. The flex circuit is typically comprised of flexible organic substrates that allow for flexible routing of the electrical signals around components of the EAM.

During an assembly of the EAM, in a first step, a first set of contacts of the plurality of ASICs are interconnected to a second set of contacts of the flexible circuit. In a second step, the first set of contacts of the plurality of ASICs are interconnected to a third set of contacts of an acoustic stack including the transducer cells. Each contact of each ASIC may be individually connected to a corresponding transducer cell and a corresponding contact of the flexible circuit, resulting in a high degree of interconnection complexity with a large number of individual connections. The high degree of interconnection complexity may increase a cost of the EAM.

To reduce the cost of the EAM, a proposed design for the EAM relies on using an interposer with high complexity to make a first level of interconnection for the EAMs, with simplified outputs. The interposer may then be connected to the flex with less complexity, resulting in a flex with less layers that may be manufactured more inexpensively than current transducer array designs, which may rely on a flexible substrate with higher complexity. By connecting the ASICs with the flex via the interposer, an overall cost of the EAM may be advantageously reduced.

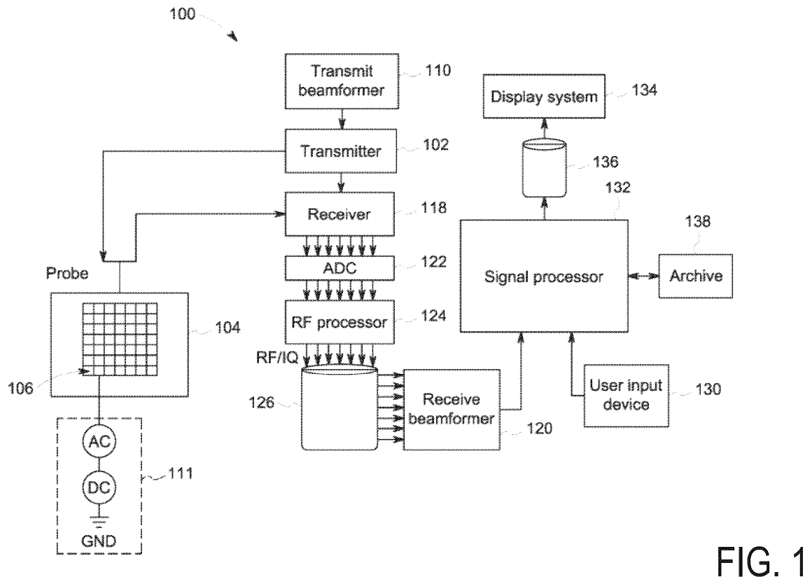

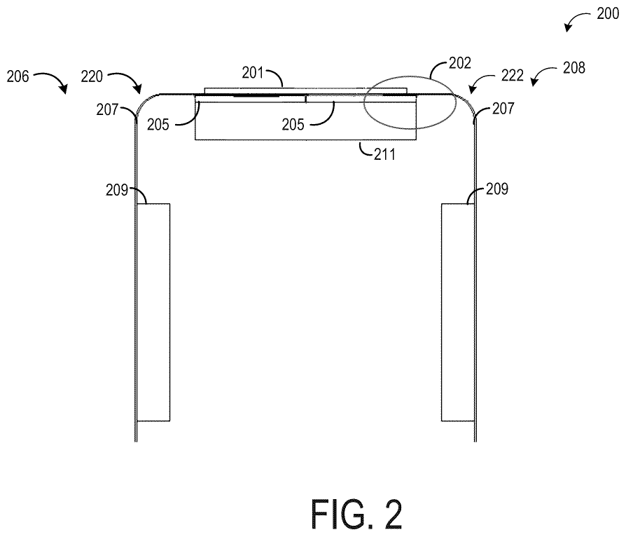

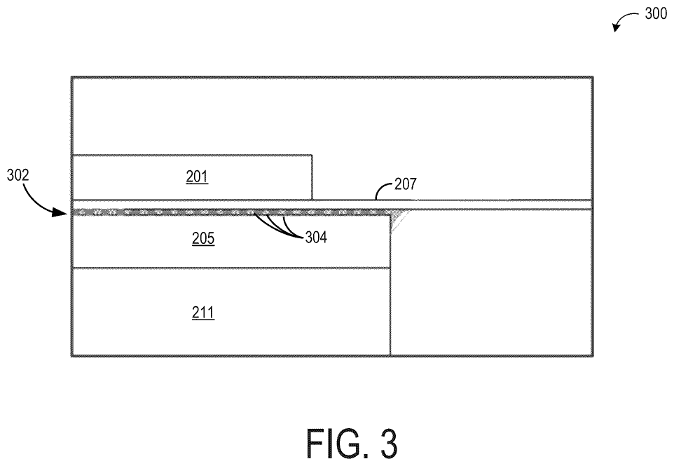

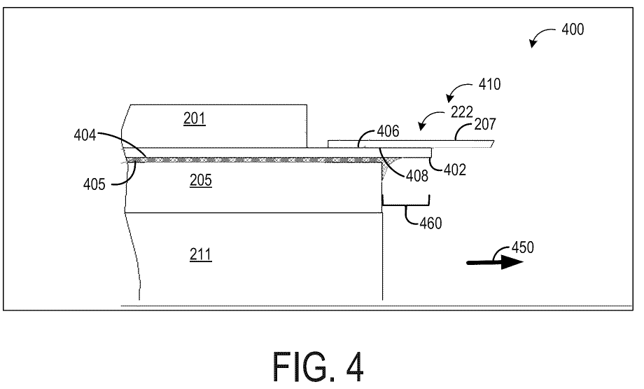

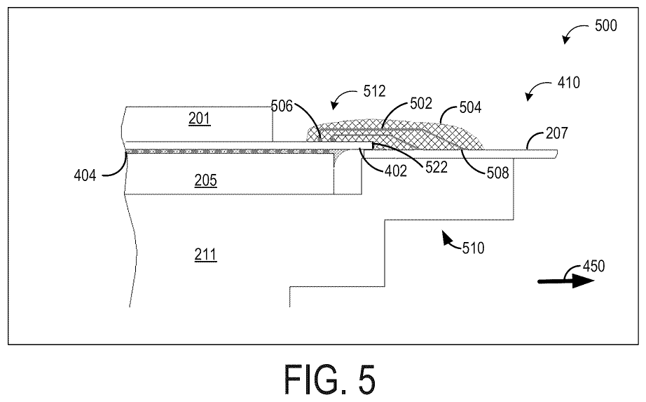

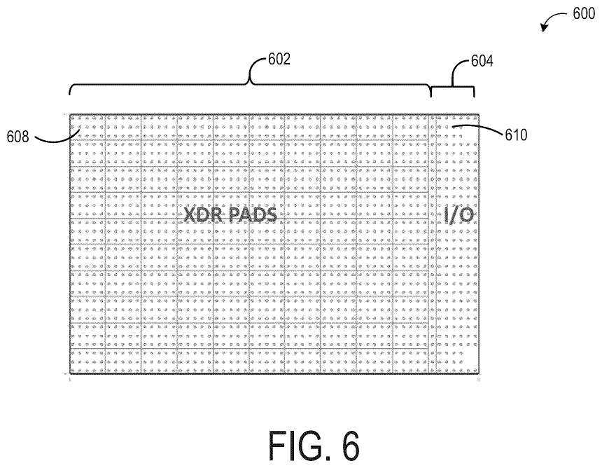

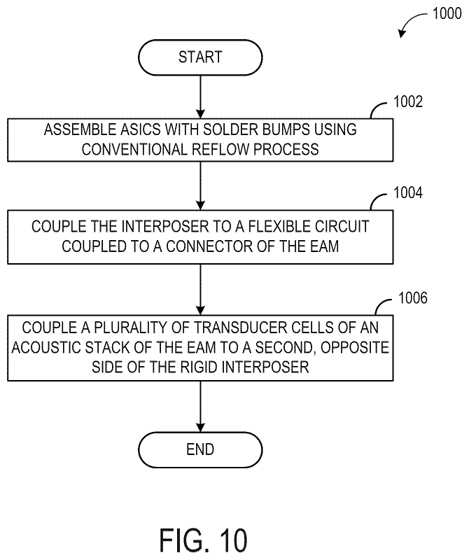

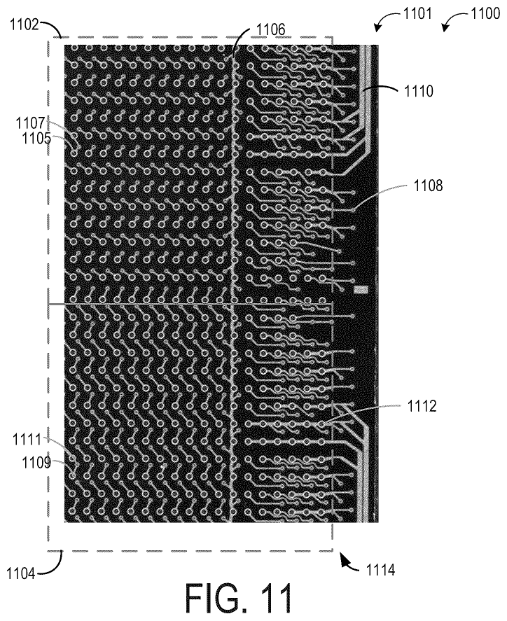

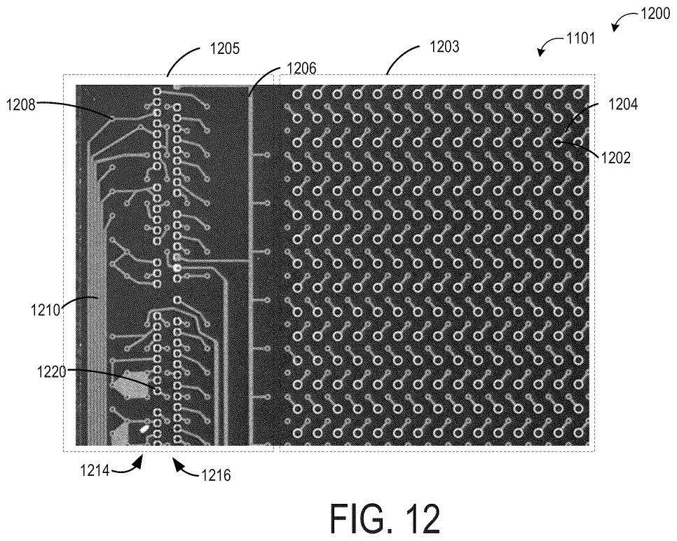

FIG. 1 shows an exemplary ultrasound system, including an ultrasound probe. The ultrasound probe may include a plurality of EAMs, where each EAM may have an architecture shown in FIG. 2. An exploded portion of the architecture is shown in FIG. 3, where an ASIC of the EAM may be coupled to an acoustic stack of the EAM via a flexible circuit. FIG. 4 shows a first proposed alternative architecture corresponding to the exploded portion, and FIG. 5 shows a second proposed alternative architecture corresponding to the exploded portion. FIGS. 6-9 show exemplary configurations of a single ASIC, a plurality of tiled ASICs, an acoustic stack of transducer cells, and an interconnection between an ASIC, an acoustic stack, and a flexible circuit, respectively. FIG. 10 shows an exemplary method for assembling an EAM including the rigid interposer. FIG. 11 shows a first side of the rigid interposer, and FIG. 12 shows a second side of the rigid interposer.

FIGS. 2-9, 11, and 12 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example.

Turning now to the figures, FIG. 1 is a block diagram of an exemplary ultrasound system 100 that may be used in ultrasound imaging, in accordance with various embodiments. The ultrasound system 100 comprises a transmitter 102, an ultrasound probe 104, a transmit beamformer 110, a receiver 118, a receive beamformer 120, A/D converters 122, an RF processor 124, an RF/IQ buffer 126, a user input device 130, a signal processor 132, an image buffer 136, a display system 134, and an archive 138. The circuit 111 is a non-limiting example of bias of a cMUT and variations in a configuration of the circuit 111 are possible without departing from the scope of the present disclosure.

The transmitter 102 may comprise suitable logic, circuitry, interfaces and/or code that may be operable to drive the ultrasound probe 104. The ultrasound probe 104 may comprise a group of transducer elements 106 that may each include, for example, a plurality of transducer cells (e.g., cMUTs). Transducer elements 106 may be arranged in EAMs, such as the EAM shown in FIG. 2, where each EAM includes a transducer array and at least a dedicated ASIC chip to pilot transducer signals from the transducer array. The cMUTs may comprise, for example, a single cMUT, a 1D array of cMUTs, 2D array of cMUTs, an annular (ring) array of cMUTs, etc. In certain embodiments, the ultrasound probe 104 may be operable to acquire ultrasound image data covering, for example, at least a substantial portion of an anatomy, such as the heart, a blood vessel, or any suitable anatomical structure. Each of the transducer elements 106 may be referred to as a channel.

The transmit beamformer 110 may comprise suitable logic, circuitry, interfaces and/or code that may be operable to control the transmitter 102 that drives the group of transducer elements 106 to emit ultrasonic transmit signals into a region of interest (e.g., human, animal, underground cavity, physical structure and the like). The transmitted ultrasonic signals may be backscattered from structures in the object of interest, like blood cells or tissue, to produce echoes. The echoes can then be received by the transducer elements 106. For example, one or more drive circuits 111 may be coupled to and drive or control the electrodes of each transducer element 106. For example, the one or more drive circuits may be coupled to separate AC and DC voltage sources.

The group of transducer elements 106 in the ultrasound probe 104 may be operable to convert the received echoes into analog signals and communicated to a receiver 118. Specifically, the analog signals may be converted from the received echoes at each of a plurality of cMUTs of a transducer element 106, and the analog signals of the plurality of cMUTs may be bundled into a single analog signal outputted by the transducer element 106. The receiver 118 may comprise suitable logic, circuitry, interfaces and/or code that may be operable to receive the signals from the ultrasound probe 104. The analog signals may be communicated to one or more of the plurality of A/D converters 122.

Accordingly, the ultrasound system 100 may multiplex such that ultrasonic transmit signals are transmitted during certain time periods and echoes of those ultrasonic signals are received during other time periods. Although not shown explicitly, various embodiments of the disclosure may allow simultaneous transmission of ultrasonic signals and reception of echoes from those signals. In such cases, the probe may comprise transmit transducer elements and receive transducer elements.

The plurality of A/D converters 122 may comprise suitable logic, circuitry, interfaces and/or code that may be operable to convert the analog signals from the receiver 118 to corresponding digital signals. The plurality of A/D converters 122 are disposed between the receiver 118 and the RF processor 124. Notwithstanding, the disclosure is not limited in this regard. Accordingly, in some embodiments, the plurality of A/D converters 122 may be integrated within the receiver 118.

The RF processor 124 may comprise suitable logic, circuitry, interfaces and/or code that may be operable to demodulate the digital signals output by the plurality of A/D converters 122. In accordance with an embodiment, the RF processor 124 may comprise a complex demodulator (not shown) that is operable to demodulate the digital signals to form I/Q data pairs that are representative of the corresponding echo signals. The RF data, which may be, for example, I/Q signal data, real valued RF data, etc., may then be communicated to an RF/IQ buffer 126. The RF/IQ buffer 126 may comprise suitable logic, circuitry, interfaces and/or code that may be operable to provide temporary storage of the RF or l/Q signal data, which is generated by the RF processor 124.

Accordingly, various embodiments may have, for example, the RF processor 124 process real valued RF data, or any other equivalent representation of the data, with an appropriate RF buffer 126. The receive beamformer 120 may comprise suitable logic, circuitry, interfaces and/or code that may be operable to perform digital beamforming processing to sum, for example, delayed, phase shifted, and/or weighted channel signals received from the RF processor 124 via the RF/IQ buffer 126 and output a beam summed signal. The delayed, phase shifted, and/or weighted channel data may be summed to form a scan line output from the receive beamformer 120, where the scan line may be, for example, complex valued or non-complex valued. The specific delay for a channel may be provided, for example, by the RF processor 124 or any other processor configured to perform the task. The delayed, phase shifted, and/or weighted channel data may be referred to as delay aligned channel data.

The resulting processed information may be the beam summed signal that is output from the receive beamformer 120 and communicated to the signal processor 132. In accordance with some embodiments, the receiver 118, the plurality of A/D converters 122, the RF processor 124, and the beamformer 120 may be integrated into a single beamformer, which may be digital. In various embodiments, the ultrasound system 100 may comprise a plurality of receive beamformers 120.

The user input device 130 may be utilized to input patient data, scan parameters, settings, select protocols and/or templates, and the like. In an exemplary embodiment, the user input device 130 may be operable to configure, manage, and/or control operation of one or more components and/or modules in the ultrasound system 100. In this regard, the user input device 130 may be operable to configure, manage and/or control operation of the transmitter 102, the ultrasound probe 104, the transmit beamformer 110, the receiver 118, the receive beamformer 120, the RF processor 124, the RF/IQ buffer 126, the user input device 130, the signal processor 132, the image buffer 136, the display system 134, and/or the archive 138. The user input device 130 may include switch(es), button(s), rotary encoder(s), a touchscreen, motion tracking, voice recognition, a mouse device, keyboard, camera, and/or any other device capable of receiving a user directive. In certain embodiments, one or more of the user input devices 130 may be integrated into other components, such as the display system 134 or the ultrasound probe 104, for example. As an example, user input device 130 may comprise a touchscreen display.

The signal processor 132 may comprise suitable logic, circuitry, interfaces and/or code that may be operable to process ultrasound scan data (e.g., summed IQ signal) for generating ultrasound images for presentation on a display system 134. The signal processor 132 is operable to perform one or more processing operations according to a plurality of selectable ultrasound modalities on the acquired ultrasound scan data. In an exemplary embodiment, the signal processor 132 may be operable to perform display processing and/or control processing, among other things. Acquired ultrasound scan data may be processed in real-time during a scanning session as the echo signals are received. Additionally or alternatively, the ultrasound scan data may be stored temporarily in the RF/IQ buffer 126 during a scanning session and processed in a live or off-line operation. In various embodiments, the processed image data can be presented at the display system 134 and/or stored at the archive 138. The archive 138 may be a local archive, a Picture Archiving and Communication System (PACS), or any suitable device for storing images and related information.

The signal processor 132 may comprise one or more central processing units, microprocessors, microcontrollers, and/or the like. The signal processor 132 may be an integrated component, or may be distributed across various locations, for example. In an exemplary embodiment, the signal processor 132 may be capable of receiving input information from the user input device 130 and/or the archive 138, generating an output displayable by the display system 134, and manipulating the output in response to input information from the user input device 130, among other things. The signal processor 132 may be capable of executing any of the method(s) and/or set(s) of instructions discussed herein in accordance with the various embodiments, for example.

The ultrasound system 100 may be operable to continuously acquire ultrasound scan data at a frame rate that is suitable for the imaging situation in question. Typical frame rates may range from 20-120 but may be lower or higher. The acquired ultrasound scan data may be displayed on the display system 134 at a display-rate that can be the same as the frame rate, or slower or faster. An image buffer 136 is included for storing processed frames of acquired ultrasound scan data that are not scheduled to be displayed immediately. Preferably, the image buffer 136 is of sufficient capacity to store at least several minutes worth of frames of ultrasound scan data. The frames of ultrasound scan data are stored in a manner to facilitate retrieval thereof according to its order or time of acquisition. The image buffer 136 may be embodied as any known data storage medium.

The display system 134 may be any device capable of communicating visual information to a user. For example, a display system 134 may include a liquid crystal display, a light emitting diode display, and/or any suitable display or displays. The display system 134 can be operable to present ultrasound images and/or any suitable information.

The archive 138 may be one or more computer-readable memories integrated with the ultrasound system 100 and/or communicatively coupled (e.g., over a network) to the ultrasound system 100, such as a Picture Archiving and Communication System (PACS), a server, a hard disk, floppy disk, CD, CD-ROM, DVD, compact storage, flash memory, random access memory, read-only memory, electrically erasable and programmable read-only memory and/or any suitable memory. The archive 138 may include databases, libraries, sets of information, or other storage accessed by and/or incorporated with the signal processor 132, for example. The archive 138 may be able to store data temporarily or permanently, for example. The archive 138 may be capable of storing medical image data, data generated by the signal processor 132, and/or instructions readable by the signal processor 132, among other things.

Components of the ultrasound system 100 may be implemented in software, hardware, firmware, and/or the like. The various components of the ultrasound system 100 may be communicatively linked. Components of the ultrasound system 100 may be implemented separately and/or integrated in various forms. For example, the display system 134 and the user input device 130 may be integrated as a touchscreen display. Additionally, while the ultrasound system 100 was described to comprise one receive beamformer 120, one RF processor 124, and one signal processor 132, various embodiments of the disclosure may use various number of processors. For example, various devices that execute code may be referred to generally as processors. Various embodiments may refer to each of these devices, including each of the RF processor 124 and the signal processor 132, as a processor. Furthermore, there may be other processors to additionally perform the tasks described as being performed by these devices, including the receive beamformer 120, the RF processor 124, and the signal processor 132, and all of these processors may be referred to as a “processor” for ease of description.

FIG. 2 shows an exemplary prior art EAM 200, comprising an acoustic stack 201, two ASICs 205, one or more flex interconnects 207, one or more connectors 209, and an acoustic backing 211. In one embodiment, acoustic stack 201 may include one or more transducer arrays of cMUTs, pMUTs, or traditional piezoelectric elements, where micromachined elements may be actuated by ultrasonic signals in a receive mode, or may generate an ultrasonic signal when driven by an appropriate electrical signal, in a transmit mode. An example material for cMUT elements is silicon. In another example embodiment, the transducer array 201 may comprise an array of piezoelectric elements, where piezoelectric materials mechanically vibrate, and thus generate ultrasonic signals, when a voltage is applied, or conversely generate an electrical signal when an ultrasonic signal impinges on the material.

Each ASIC 205 may comprise circuitry for driving and/or receiving signals from acoustic stack 201 and therefore may comprise processing, amplification, transmission, and receiver circuitry, for example. For example, ASIC 205 may provide electrical signals to the cMUTs or piezoelectric elements in the transducer arrays of acoustic stack 201 to generate ultrasonic signals, or may receive electrical signals from the transducer arrays when exposed to ultrasonic signals.

Each flex interconnect 207 may comprise a flat, flexible electrical interconnection device comprising conductive traces within flexible insulating material, such as polyimide, for example. In this manner, electrical signals may be communicated between the connector 209 and ASIC 205 with a flexible and configurable physical connector. In the depicted embodiment, flex interconnect 207 includes a first wing 220 extending from a first side 206 of EAM 200, and a second wing 222 extending from a second side 208 of EAM 200. In other embodiments, flex interconnect 207 may include a greater or lesser number of wings, and/or may extend across a full length of a surface of ASIC 205, depending on the desired configuration.

Each connector 209 may comprise an electrical and mechanical connector for EAM 200, where electrical signals may be communicated between the EAM 200 and external circuitry of an ultrasound imaging system. In addition, connector 209 may mechanically affix EAM 200 to a supporting structure, such as a printed circuit board or other suitable substrate.

EAM 200 may be designed to occupy a footprint equal to, or smaller than an active area of acoustic stack 201, thus allowing the tiling of additional EAMs on four sides of a given EAM without significant gaps in the larger, overall tiled 2D transducer array. EAM 200 may include acoustic backing 211 underneath ASIC 205 to provide isolation from ultrasonic signals. A portion 202 of FIG. 2 is shown in greater detail in exploded view 300 of FIG. 3.

Referring now to FIG. 3, an exploded view 300 of EAM 200 is shown, where exploded view 300 shows a positioning of flex interconnect 207 with respect to acoustic stack 201 and ASIC 205. In particular, in an interface 302 between flex interconnect 207 and ASIC 205, a plurality of connections 304 are shown, where each connection 304 connects an individual ASIC contact (which pilots an individual transducer cell of a transducer array of ASIC 205) to a corresponding contact on flex interconnect 207.

A more detailed understanding of the arrangement of the connections 304 may be gained from FIGS. 6-9. FIG. 6 shows an exemplary ASIC 600 of an EAM, which may be a non-limiting example of ASIC 205 of FIGS. 2 and 3. ASIC 600 includes a first two-dimensional (2D) array 602 of internal contacts 608, and a second 2D array 604 of output contacts 610. The internal contacts 608 may be electrically coupled to a corresponding transducer cell of a transducer array positioned in an adjacent acoustic stack (e.g., acoustic stack 201).

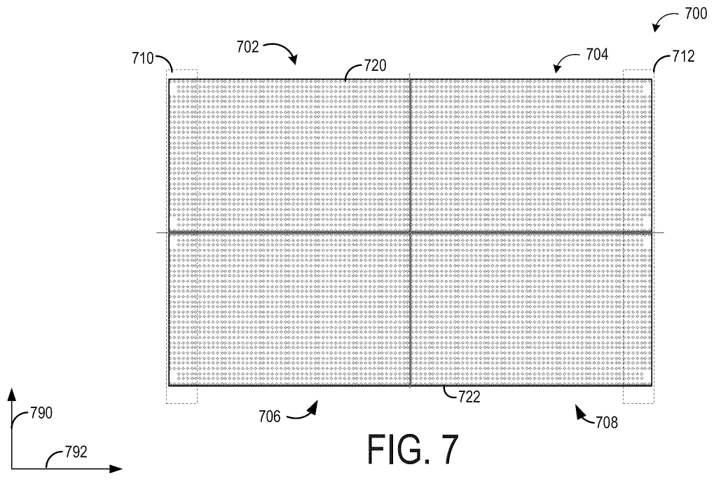

FIG. 7 shows an exemplary tiled ASIC configuration 700, including a first ASIC 702, a second ASIC 704, a third ASIC 706, and a fourth ASIC 708 arranged in a 2×2 array. Tiled ASIC configuration 700 is depicted in a plane defined vertically by an elevation 790 and horizontally by an azimuth 792.

In other examples, tiled ASIC configuration 700 may include a greater or lesser number of ASICs. For example, tiled ASIC configuration 700 may include a 3×3 array of ASICs. In FIG. 7, the output contacts of ASICs 702 and 706 (e.g., output contacts 610) are arranged within a dashed box 710, while the output contacts of ASICs 704 and 708 are arranged within a dashed box 712. In other embodiments, the output contacts of ASICs 702, 704, 706, and 708 may be arranged along different edges of tiled ASIC configuration 700, such as a top edge 720 and a bottom edge 722.

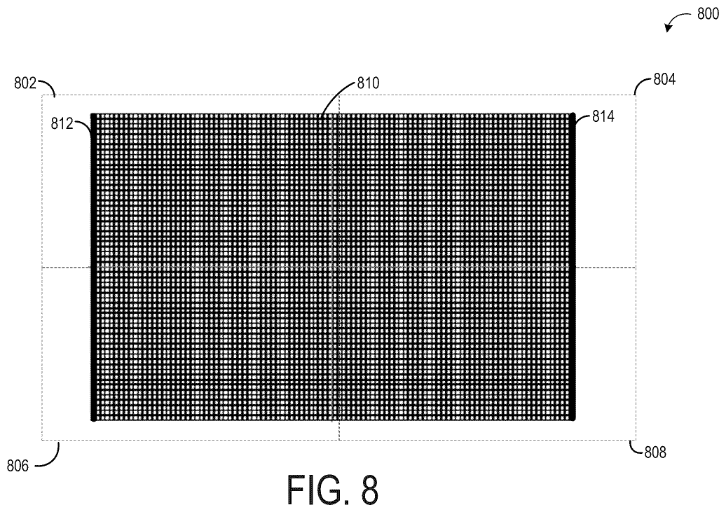

FIG. 8 shows an exemplary acoustic stack 800 that may be electrically coupled to tiled ASIC configuration 700. Acoustic stack 800 includes a plurality of transducer cells 810. Acoustic stack 800 may be arranged adjacent to tiled ASIC configuration 700, such that each transducer cell 810 is aligned adjacent to a corresponding internal contact (e.g., internal contact 608) of an ASIC of tiled ASIC configuration 700 in a manner that facilitates interconnection between each transducer cell 810 with a corresponding internal contact of an adjacent ASIC (e.g., internal contact 608). Specifically, a first portion 802 of transducer cells 810 may be aligned with ASIC 702; a second portion 804 of transducer cells 810 may be aligned with ASIC 704; a third portion 806 of transducer cells 810 may be aligned with ASIC 706; and a fourth portion 808 of transducer cells 810 may be aligned with ASIC 708. Tiled ASIC configuration 700 further includes a first ground connection 812 and a second ground connection 814, where each transducer cell 802 may be electrically coupled to one of first ground connection 812 and second ground connection 814. Each transducer cell of acoustic stack 800 may then be electrically coupled to a corresponding internal contact of a corresponding ASIC via an individual electrical connection.

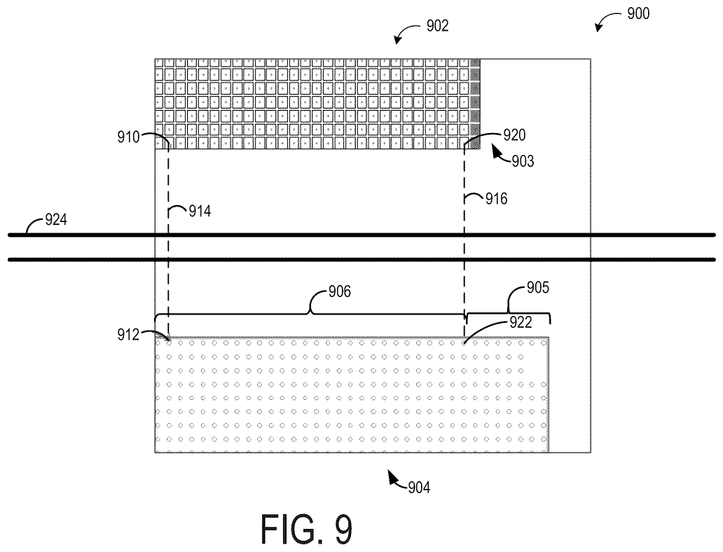

FIG. 9 shows a connection diagram 900, including an acoustic stack 902 and an ASIC 904 arranged adjacent to each other. Acoustic stack 902 may be a non-limiting example of acoustic stack 800, and ASIC 904 may be a non-limiting example of ASICs 702, 704, 706, and 708 of FIG. 7, ASIC 600 of FIG. 6, and ASIC 205 of FIGS. 2 and 3. Acoustic stack 902 includes a plurality of ground connections 903 (e.g., first ground connection 812 or second ground connection 814). ASIC 904 includes a 2D array 906 of internal contacts (e.g., internal contact 608), and a 2D array 905 of output contacts (e.g., output contact 610). Each transducer cell of acoustic stack 902 may be electrically coupled to a corresponding internal contact of 2D array 906. For example, a first transducer cell 910 of acoustic stack 902 may be electrically coupled to a corresponding internal contact 912 of ASIC 904, and a second transducer cell 920 of acoustic stack 902 may be electrically coupled to a corresponding internal contact 922 of ASIC 904. Thus, a number of individual connections between acoustic stack 902 and ASIC 904 may be large.

Returning now to FIG. 3, due to the large number of electrical interconnections between acoustic stack 201, ASIC 205, and flex interconnect 207, as exemplified by FIGS. 6-9, a complexity and cost of flex interconnect 207 may be high. For example, ASICs 205/904) may include 1500 transducer cells, making it almost impossible to pilot each transducer cell from an external contact (more than 1500 input/output (I/O) contacts+power and ground). As described in more detail below, in a proposed design, the transducer cells may be grouped into groups, for example, of 15 cells, where one of the functions of the ASIC is to pilot each group rather than each individual cell. This decreases the number of I/O's to pilot the transducer cells to 100, which can be managed far more easily and at a lower cost. Thus, to reduce the cost of flex interconnect 207, an alternative architecture of EAM 200 may be used, as shown in FIG. 4.

Referring now to FIG. 4, a first alternative architecture 400 of EAM 200 is shown, corresponding to exploded view 300 of the prior art FIG. 3. In FIG. 4, a plurality of electrical connections between acoustic stack 201, ASIC 205, and wing 220 of flex interconnect 207 are established via a rigid interposer 402 arranged between acoustic stack 201 and ASIC 205. For simplicity, wing 220 and/or other wings of flex interconnect 207 are not shown, although wing 220 and/or the other wings may be similarly configured. In first alternative architecture 400, wing 222 of flex interconnect 207 may not be in face-sharing contact with ASIC 205, as shown in FIG. 3. A lower surface 406 of wing 222 of flex interconnect 207 may be in face-sharing contact with an upper surface of top side 408 of interposer 402. In one of the proposed configurations, a plurality of contacts 405 of ASIC 205 may comprise solder bumps, and ASIC 205 may be assembled to interposer 402 through solder reflow. A layer of underfill 404 may be included between interposer 402 and ASIC 205, which may serve to reinforce mechanically the assembly and may improve a transmission of ultrasound signals.

Interposer 402 may comprise a plurality of conductive traces and insulating material for providing electrical contact between the transducer array of acoustic stack 201 and ASIC 205. For example, contacts on ASIC 205 may not be adjacent to and/or have the same location as corresponding contacts of the transducer cells of acoustic stack 201. The use of interposer 402 may enable the interconnection of these devices without having to design the devices with identical placement of contacts, thereby reducing a complexity of EAM 200.

In various embodiments, interposer 402 may be an organic substrate. An ideal organic substrate may have a low Coefficient of Thermal Expansion (CTE), a low cost, a low development cost, and a low thickness. For example, interposer 402 may be Bismaleimide Triazine (BT) substrate, for which a 0.15 mm thickness is achievable with four metal layers. In other embodiments, interposer 402 may be a glass or a silicon substrate with through vias connecting a first side of the substrate with a second, opposite side of the substrate, thereby allowing contact redistribution on both sides. A disadvantage of the glass and silicon substrate is that the development cost may be higher than for the organic substrate. Additionally, the thickness of the interposer may be greater (0.4 mm, for example).

In various embodiments, interposer 402 may be a rigid interposer that is compatible with conventional assembly techniques used for assembling ASIC 205. In particular, the rigid interposer may be compatible with a conventional and widely spread ASIC assembly via a reflow process, meaning melting the solder alloy forming the contacts 405 to form a contact with the interposer. Thanks to substrate rigidity, ASIC with solder bumps (very conventional technique, widely spread within subcontractors) can be assembled by reflow (more difficult with a flex due to is CTE far away from silicon (ASIC) CTE and flex flexibility).

Interconnections between interposer 402 and a wing 410 of flex interconnect 207 may be established at a top side 408 of interposer 402, where top side 408 is on the side of acoustic stack 201. An advantage of forming the interconnections at top side 408 is that an increase 460 in a length of EAM 200 in an azimuth direction (indicated by arrow 450) with respect to the prior art shown in FIG. 3 (and/or an elevation direction, not shown in FIG. 4) may be reduced and/or limited. In some embodiments, the interconnections between interposer 402 and wing 410 of flex interconnect 207 may be formed with Anisotropic Conductive Film (ACF) and/or Anisotropic Conductive Paste (ACP), where conductive particles embedded in the ACF are compressed by applying pressure during a bonding process. When the conductive particles are compressed, the conductive particles ensure conduction between contacts (e.g., electrodes) of ASIC 205 (e.g., contacts 610 of FIG. 6).

Creating the interconnections via ACF/ACP may simplify an assembly of EAM 200. This interconnexion with ACF/ACP will be privileged to limit azimuth or elevation length and to simplify this assembly operation (no need to make specific contact finishing on both flex and interposer). Additionally, as both ACF and ACP rely on high pressure during assembly, interposer 402 and contacts with flex interconnect 207 may be positioned with respect to ASIC 205 to have a flat support during the assembly. For example, a face-sharing contact between interposer 402 and contacts of flex interconnect 207 may be positioned above the ASIC such that the ASIC provides a flat support for ACF/ACP application at high pressure.

Referring now to FIG. 5, a second alternative architecture 500 of EAM 200 is shown, corresponding to exploded view 300 of FIG. 3. In FIG. 5, the connection between wing 222 of flex interconnect 207 and interposer 402 is established via a plurality of wire bonds 502, where each wire bond 502 is formed between a first contact (e.g., electrode) 506 of interposer 402 and a second contact 508 of flex interconnect 207. First contact 506 may be positioned at a side portion 512 of interposer 402 located proximal to flex interconnect 207, to reduce a length of the wire bonds 502. Side portion 512 is described in greater detail below in reference to FIGS. 11 and 12. Additionally, in second alternative architecture 500, a shape of acoustic backing 211 may be altered to provide adequate support of flex interconnect 207 during wire-bonding. For example, a portion 510 of acoustic backing 211 may extend in the azimuth direction 450 under flex interconnect 207 to provide the support.

Protection for the wire bonds 502 may be provided by an encapsulant applied as a glob-top 504. An advantage of second alternative architecture 500 over first alternative architecture 400 is that less contacts are established between flex interconnect 207 and interposer 402, since a single wire bond 502 can handle large currents (e.g., larger than 500 mA). However, more assembly steps may be performed (e.g., assembling flex wing 410 to backing 211, applying the encapsulant to the wire bonds 502 for glob-top 504, and placing a gasket 522 prior to applying the encapsulant to avoid leakage of liquid encapsulant before curing of the encapsulant. An additional disadvantage of second alternative architecture 500 is that the azimuth length of EAM 200 may be longer. In one example, the length of EAM 200 may be 6 mm longer with second alternative architecture 500 than with first alternative architecture 400.

Referring now to FIG. 10, an exemplary method 1000 is shown for manufacturing an EAM, such as EAM 200 of FIG. 2, with an alternative architecture such as alternative architecture 400 of FIG. 4 or alternative architecture 500 of FIG. 5. It should be appreciated that method 1000 is provided as a simplified method, where the simplified method includes steps relevant to the systems and methods disclosed herein, e.g., the inclusion of a rigid interposer for facilitating electrical connections between a plurality of ASICs and a flexible circuit. As such, other steps in manufacturing the EAM that are not relevant to the systems and methods disclosed herein are intentionally left out.

Method 1000 starts at 1002, where method 1000 includes assembling a plurality of ASICs of the EAM. The ASICs may be non-limiting examples of ASIC 205 and/or ASICs 600, 702, 704, 706, and 708 of FIGS. 6 and 7, respectively. In a first step, the ASICs may be assembled with solder bumps, in a conventional reflow process typically used in ASIC assembly. In a second step, for acoustic purpose (transmission of ultrasound signals), an underfill resin may be added to fill a gap between the rigid interposer and the ASICs. The rigid interposer may be the same as or similar to rigid interposer 402 of FIGS. 4 and 5. In some embodiments, the rigid interposer may include Bismaleimide Triazine (BT), or a different organic substrate with a low CTE, low cost and development cost, and low thickness. In other embodiments, the rigid interposer may include a glass or silicon substrate with through vias connecting the first side of the rigid interposer with a second, opposite side of the rigid interposer, thereby allowing contact redistribution between the first side and the second side.

FIG. 11 shows a first side 1100 of an exemplary interposer 1101, which may be a non-limiting example of rigid interposer 402. In the depicted embodiment, interposer 1101 is a glass or silicon interposer, including through vias connecting both sides of interposer 1101. In other embodiments, interposer 1101 may be an organic interposer of two layers, where the through vias may connect both sides of interposer 1101. In still other embodiments, interposer 1101 may be an organic interposer including more than two layers, where the through vias may not connect both sides of interposer 1101. In the depicted example, first side 1100 is coupled to two ASICs, where a first portion 1102 of contacts 1105 on interposer 1101 may be connected to a first ASIC, and a second portion 1104 of contacts 1109 on interposer 1101 may be connected to a second ASIC (e.g., the first ASIC and the second ASIC are tiled). In some examples, the first ASIC and the second ASIC may be included within a larger tiled configuration of ASICs of an EAM, such as tiled configuration 700 of FIG. 7. Contacts 1105 may be connected to the transducer cells via a respective plurality of through vias 1107, and contacts 1109 via a respective plurality of through vias 1111.

First side 1100 includes a redistribution line 1106 for ground connection, and various other redistribution lines 1110, which may simplify the interposer output (e.g. contacts on side 406 of FIG. 4) combined with redistribution lines on the other side (e.g. redistribution lines 1210 of FIG. 12 described below). A portion 1114 of first side 1100 includes various columns of ASIC output contacts 1112 (e.g., ground, power, I/Os), where each output contact 1112 may correspond to one ASIC bond pad. Portion 1114 also includes various through vias 1108.

Returning to method 1000, at 1004, method 1000 includes coupling the rigid interposer to at least one flexible circuit (e.g., flex interconnect 207) of the EAM, where the flexible circuit is electrically coupled to one or more connectors of the EAM (e.g., connectors 209). In some examples, an electrical test of the coupling between the at least one ASIC and the flexible circuit may be performed, even prior to assembling the acoustic stack.

In some embodiments, the rigid interposer may be coupled to the flexible circuit using ACF/ACP, as in the first alternative configuration of EAM 200 shown in FIG. 4, which may simplify an assembly of EAM 200 as described above. During a first coupling process using ACF/ACP, the ACF/ACP may be applied between a first set of electrodes arranged on a first surface of the interposer (e.g., contacts 1220 of FIG. 12) and a second set of electrodes of a second, opposing surface of the flexible circuit. A pressure may be applied to compress the ACF/ACP between the first surface and the second surface. When the pressure is applied, a first set of conductive particles embedded in the ACF/ACP and positioned between the first set of electrodes and the second set of electrodes may be compressed, allowing conduction between opposing electrode pairs of the first set of electrodes and the second set of electrodes. A second set of conductive particles embedded in the ACF/ACP and positioned around the first set of electrodes and the second set of electrodes may not be compressed, and may not be conductive, thereby providing insulation between the electrode pairs. During bonding of the rigid interposer and the flexible circuit, an underlying ASIC and/or a backing (e.g., backing 211) may be used as a flat support to facilitate applying the pressure.

In other embodiments, the rigid interposer may be coupled to the flexible circuit using a wire bonding process, as in the second alternative configuration of EAM 200 shown in FIG. 5. During the wire bonding process, wire bonds (e.g., wire bonds 502 of FIG. 5) are formed between output contacts (e.g., output contacts 1220 of FIG. 12) of the rigid interposer and contacts of the flexible circuit (e.g., contacts 508). During the wire bonding process, support for pressure used to form the wire bonds may be provided by one or more ASICs positioned at an opposite side of the rigid interposer and/or a backing material (e.g., backing 211), as described above.

An advantage of the wire bonding process over using ACF/ACP is that a number of contacts used to form the interconnections between the flexible circuit and the rigid interposer may be reduced, since a single wire can accommodate large currents (e.g., more than 500 mA of continuous power). However, a disadvantage of the wire bonding process with respect to using ACF/ACP is that a greater number of steps may be performed during an assembly of the EAM. The wire bonding process may include assembling portions of the flexible circuit (e.g., wings) to the backing, placing a gasket (e.g., gasket 522) to prevent encapsulant leakage, and then applying an encapsulant as a glob-top (e.g., glob-top 504) to cover and protect the wire bonds. Another disadvantage of the wire bonding process is that an azimuth length of the EAM may be increased. In one example, the azimuth length is increased by at least 6 mm.

Returning to method 1000, at 1006, method 1000 includes physically and electrically coupling a plurality of transducer cells of an acoustic stack of the EAM to the second, opposite side of the rigid interposer. When the transducer cells are coupled to the second, opposite side, electrical connections are established between each transducer cell on the second side of the rigid interposer and a corresponding contact of a corresponding ASIC on the first side of the rigid interposer (e.g., a through via connection). In other words, the transducer cells are coupled to contacts of a corresponding ASIC positioned at an opposite side of the rigid interposer via the rigid interposer, as opposed to via a flexible circuit, as is typically done.

FIG. 12 shows a second side 1200 of interposer 1101 of FIG. 11, where second side 1200 is coupled to an acoustic stack of an EAM (e.g., acoustic stack 201 and/or acoustic stack 800). In the depicted example, a first portion 1203 of second side 1200 includes a plurality of contacts 1202, where each contact 1202 may be electrically connected to an individual transducer cell of the acoustic stack. After second side 1200 is coupled to the acoustic stack, each contact 1202 may be electrically coupled to a corresponding contact of an ASIC on the first side 1100 of interposer 1101 through a respective through via 1204.

A second portion 1205 of second side 1200 includes a first column 1214 and a second column 1216 of interposer output contacts 1220, which may be used for wire bonding to a flexible circuit (e.g., portion 512 of FIG. 5). Second portion 1205 also includes various through vias 1208, a redistribution line 1206 for a ground connection, and various other redistribution lines 1210, similar to first side 1100 of FIG. 11. It should be appreciated that the exemplary contacts, vias, lines, and other components of interposer 1101 shown in FIGS. 11 and 12 are for illustrative purposes, and other embodiments may include different arrangements and/or numbers of the contacts, vias, lines, and other components without departing from the scope of this disclosure.

Thus, two alternative architectures for an EAM are proposed that may reduce a cost of the EAM, by imposing high complexity at the interposer level and decreasing the complexity of interconnections elsewhere, such as by simplifying I/O contacts (e.g., contacts 610 of FIG. 6). Additionally, a design of the flex interconnect may be simplified. A distance between an ASIC and the interposer after assembly may be increased, thereby increasing an efficiency of dispensing an underfilling. In one example, a first, typical pitch of passive components may be equal to or higher than 0.5 mm, compared to a second pitch of the proposed EAM of 0.2-0.3 mm. The proposed architecture may be applied to various types of probes having a matrix array of transducers. Alternative approaches to redesigning the EAM interconnections, such as I/Os contacts redistribution via a redistribution layer (RDL) at a single ASIC level may be more expensive, and/or may not significantly simplify the output flex circuits (e.g., redundancy of I/Os between ASICs). RDL at the level of the EAM (e.g., four ASICs, in the preferred option) is potentially possible (Fan-Out Wafer Level), but technical feasibility and cost effectiveness may be less than desirable due to a tooling cost for limited probe volumes and for a EAM surface of ˜16×24 mm², in one example.

The technical effect of forming interconnections between transducer cells, ASIC contacts, and a flexible circuit of an EAM via a rigid interposer is that a cost of the EAM may be reduced and a complexity of interconnections of the EAM may be reduced.

The disclosure also provides support for an Electro-acoustic Module (EAM) of an ultrasound probe, the EAM comprising: an acoustic stack including a plurality of transducer cells, at least one Application Specific Integrated Circuit (ASIC) chip, and a rigid interposer positioned between the at least one ASIC chip and a flexible circuit coupled to one or more connectors of the EAM, the interposer facilitating an electrical interconnection between a plurality of internal contacts of the at least one ASIC and the flexible circuit. In a first example of the system, the rigid interposer includes an organic substrate. In a second example of the system, optionally including the first example, the organic substrate is Bismaleimide Triazine. In a third example of the system, optionally including one or both of the first and second examples, the rigid interposer includes one of a glass substrate and a silicon substrate. In a fourth example of the system, optionally including one or more or each of the first through third examples, the rigid interposer includes through vias connecting a first side of the rigid interposer with a second, opposing side of the rigid interposer, the through vias allowing contact redistribution on both of the first side and the second side. In a fifth example of the system, optionally including one or more or each of the first through fourth examples, the rigid interposer is electrically coupled to the at least one ASIC via solder bumps. In a sixth example of the system, optionally including one or more or each of the first through fifth examples, the flexible circuit includes one or more wings arranged at one or more respective sides of the acoustic stack, each wing connecting a portion of the plurality of internal contacts of the at least one ASIC with a respective connector of the one or more connectors via the rigid interposer. In a seventh example of the system, optionally including one or more or each of the first through sixth examples, a wing of the flexible circuit is electrically coupled to one of a bottom side of the rigid interposer, the bottom side of the rigid interposer electrically coupled to the at least one ASIC, and a top side of the rigid interposer, the top side of the rigid interposer electrically coupled to the transducer cells of the acoustic stack. In a eighth example of the system, optionally including one or more or each of the first through seventh examples, an electrical interconnection between the rigid interposer and the wing of the flexible circuit includes at least one of Anisotropic Conductive Film (ACF) and Anisotropic Conductive Paste (ACP). In a ninth example of the system, optionally including one or more or each of the first through eighth examples, the wing of the flexible circuit is electrically coupled to the top side of the rigid interposer, and a face-sharing contact between the rigid interposer and contacts of the wing of the flexible circuit are positioned above the at least one ASIC such that the at least one ASIC provides a flat support for ACF/ACP application at high pressure. In a tenth example of the system, optionally including one or more or each of the first through ninth examples, an electrical interconnection between the rigid interposer and the wing of the flexible circuit includes a plurality of wire bonds. In an eleventh example of the system, optionally including one or more or each of the first through tenth examples, the plurality of wire bonds are protected by an encapsulant applied as a glob-top. In a twelfth example of the system, optionally including one or more or each of the first through eleventh examples, the system further comprises: a gasket placed to avoid liquid encapsulant leakage. In a thirteenth example of the system, optionally including one or more or each of the first through twelfth examples, the wing of the flexible circuit is electrically coupled to the top side of the rigid interposer, and the EAM further comprises an acoustic backing assembled behind the at least one ASIC to support the wing of the flexible circuit during wire-bonding.

The disclosure also provides support for a method for assembling an Electro-acoustic Module (EAM) of an ultrasound probe, the method comprising: assembling at least one Application Specific Integrated Circuit (ASIC) chip of the EAM with solder bumps, using a conventional reflow process, coupling the at least one ASIC chip to a first side of a rigid interposer via the solder bumps, coupling a plurality of transducer cells of an acoustic stack to a second, opposite side of the rigid interposer, and coupling the rigid interposer to a flexible circuit coupled to a connector of the EAM, the rigid interposer facilitating an electrical interconnection between a plurality of internal contacts of the at least one ASIC and the flexible circuit. In a first example of the method, coupling the rigid interposer to the flexible circuit further comprises creating an interconnection between the rigid interposer and the flexible circuit using at least one of Anisotropic Conductive Film (ACF) and Anisotropic Conductive Paste (ACP). In a second example of the method, optionally including the first example, coupling the rigid interposer to the flexible circuit further comprises creating an interconnection between the rigid interposer and the flexible circuit via a plurality of wire bonds. In a third example of the method, optionally including one or both of the first and second examples, the method further comprises: applying an encapsulant to the plurality of wire bonds as a glob-top to protect the wire bonds. In a fourth example of the method, optionally including one or more or each of the first through third examples, the flexible circuit is electrically coupled to one of a bottom side of the rigid interposer, the bottom side of the rigid interposer electrically coupled to the at least one ASIC, and a top side of the rigid interposer, the top side of the rigid interposer electrically coupled to the transducer cells of the acoustic stack.

The disclosure also provides support for an Electro-acoustic Module (EAM) of an ultrasound probe, the EAM comprising a plurality of transducer cells, at least one Application Specific Integrated Circuit (ASIC) chip, and a flexible circuit coupled to one or more connectors of the EAM, wherein an electrical interconnection between the plurality of transducer cells, a respective plurality of internal contacts of the at least one ASIC chip, and a respective plurality of contacts of the flexible circuit are made via a rigid interposer arranged in face-sharing contact with the transducer cells at a first surface of the rigid interposer, in face-sharing contact with the at least one ASIC chip at a second surface of the rigid interposer, and in face-sharing contact with the respective plurality of contacts of the flexible circuit at either of the first surface and the second surface.

This written description uses examples to disclose the invention, including the best mode, and also to enable a person of ordinary skill in the relevant art to practice the invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

1. An Electro-Acoustic Module (EAM) of an ultrasound probe, the EAM comprising: an
acoustic stack including a plurality of transducer cells;
at least one Application Specific Integrated Circuit (ASIC) chip; and
a rigid interposer positioned between the at least one ASIC chip and a flexible circuit coupled to one or more connectors of the EAM, the interposer facilitating an electrical interconnection between a plurality of internal contacts of the at least one ASIC and the flexible circuit.

2. The EAM of claim 1, wherein the rigid interposer includes an organic substrate.

3. The EAM of claim 2, wherein the organic substrate is Bismaleimide Triazine.

4. The EAM of claim 1, wherein the rigid interposer includes one of a glass substrate and a silicon substrate.

5. The EAM of claim 1, wherein the rigid interposer includes through vias connecting a first side of the rigid interposer with a second, opposing side of the rigid interposer, the through vias allowing contact redistribution on both of the first side and the second side.

6. The EAM of claim 1, wherein the rigid interposer is electrically coupled to the at least one ASIC.

7. The EAM of claim 1, wherein the flexible circuit includes one or more wings arranged at one or more respective sides of the acoustic stack, each wing connecting a portion of the plurality of internal contacts of the at least one ASIC with a respective connector of the one or more connectors via the rigid interposer.

8. The EAM of claim 7, wherein a wing of the flexible circuit is electrically coupled to one of a bottom side of the rigid interposer, the bottom side of the rigid interposer electrically coupled to the at least one ASIC, and a top side of the rigid interposer, the top side of the rigid interposer electrically coupled to the transducer cells of the acoustic stack.

9. The EAM of claim 8, wherein an electrical interconnection between the rigid interposer and the wing of the flexible circuit includes at least one of Anisotropic Conductive Film (ACF) and Anisotropic Conductive Paste (ACP).

10. The EAM of claim 9, wherein the wing of the flexible circuit is electrically coupled to the top side of the rigid interposer, and a face-sharing contact between the rigid interposer and contacts of the wing of the flexible circuit are positioned above the at least one ASIC such that the at least one ASIC provides a flat support for ACF/ACP application at high pressure.

11. The EAM of claim 8, wherein an electrical interconnection between the rigid interposer and the wing of the flexible circuit includes a plurality of wire bonds.

12. The EAM of claim 11, wherein the plurality of wire bonds are protected by an encapsulant applied as a glob-top.

13. The EAM of claim 12, further comprising a gasket placed to avoid liquid encapsulant leakage.

14. The EAM of claim 11, wherein the wing of the flexible circuit is electrically coupled to the top side of the rigid interposer, and the EAM further comprises an acoustic backing assembled behind the at least one ASIC to support the wing of the flexible circuit during wire-bonding.

15. A method for assembling an Electro-Acoustic Module (EAM) of an ultrasound probe, the method comprising:
assembling at least one Application Specific Integrated Circuit (ASIC) chip of the EAM with solder bumps, using a conventional reflow process;
coupling the at least one ASIC chip to a first side of a rigid interposer via the solder bumps;
coupling a plurality of transducer cells of an acoustic stack to a second, opposite side of the rigid interposer; and
coupling the rigid interposer to a flexible circuit coupled to a connector of the EAM, the rigid interposer facilitating an electrical interconnection between a plurality of internal contacts of the at least one ASIC and the flexible circuit.

16. The method of claim 15, wherein coupling the rigid interposer to the flexible circuit further comprises creating an interconnection between the rigid interposer and the flexible circuit using at least one of Anisotropic Conductive Film (ACF) and Anisotropic Conductive Paste (ACP).

17. The method of claim 15, wherein coupling the rigid interposer to the flexible circuit further comprises creating an interconnection between the rigid interposer and the flexible circuit via a plurality of wire bonds.

18. The method of claim 17, further comprising applying an encapsulant to the plurality of wire bonds as a glob-top to protect the wire bonds.

19. The method of claim 15, wherein the flexible circuit is electrically coupled to one of a bottom side of the rigid interposer, the bottom side of the rigid interposer electrically coupled to the at least one ASIC, and a top side of the rigid interposer, the top side of the rigid interposer electrically coupled to the transducer cells of the acoustic stack.

20. An Electro-Acoustic Module (EAM) of an ultrasound probe, the EAM comprising a plurality of transducer cells, at least one Application Specific Integrated Circuit (ASIC) chip, and a flexible circuit coupled to one or more connectors of the EAM; wherein an electrical interconnection between the plurality of transducer cells, a respective plurality of internal contacts of the at least one ASIC chip, and a respective plurality of contacts of the flexible circuit are made via a rigid interposer arranged in face-sharing contact with the transducer cells at a first surface of the rigid interposer, in face-sharing contact with the at least one ASIC chip at a second surface of the rigid interposer, and in face-sharing contact with the respective plurality of contacts of the flexible circuit at either of the first surface and the second surface.
